(19) United States
(12) Patent Application Publication
(10) Pub. No.: US 2024/0290697 A1
(43) Pub. Date: Aug. 29, 2024

(54) POWER MODULE AND MANUFACTURING METHOD AND MOLD THEREOF

(71) Applicant: SENTEC E&E CO., LTD., Taoyuan City (TW)

(72) Inventors: Jason HUANG, TAOYUAN CITY (TW); Chang-Fu CHEN, TAOYUAN CITY (TW); Pi-Sheng HSU, TAOYUAN CITY (TW); Liang-Yo CHEN, TAOYUAN CITY (TW)

(21) Appl. No.: 18/235,345

(22) Filed: Aug. 17, 2023

Related U.S. Application Data
(60) Provisional application No. 63/447,970, filed on Feb. 24, 2023.

(51) Int. Cl. H01L 23/498; H01L 21/48; H01L 21/56; H01L 23/31; H01L 25/07

(52) U.S. Cl. CPC H01L 23/49811; H01L 21/4853; H01L 21/565; H01L 23/3121; H01L 25/072

(57) ABSTRACT

A power module, a manufacturing method, and a mold are disclosed. The power module includes a circuit substrate, a terminal assembly, and a package body. A surface of the circuit substrate is provided with at least one semiconductor component, each terminal assembly includes a terminal rack and a terminal inserted onto the terminal rack, and each terminal rack is disposed on the surface of the circuit substrate and has an insert surface and provided for passing each terminal through the insert surface into the terminal rack for combination. The package body is installed on the circuit substrate to package the semiconductor component and has an external surface substantially aligned with the insert surface of each terminal rack, or the insert surface protruding from the external surface, to make each terminal protrude out from the package body.

### CROSS-REFERENCE TO RELATED APPLICATION

This patent application claims the benefit of U.S. Provisional Patent Application No. 63/447,970, filed Feb. 24, 2023, which is incorporated by reference herein.

### BACKGROUND OF THE DISCLOSURE

### Technical Field

The technical field relates to a power semiconductor, and more particularly relates to a power module, and a manufacturing method and a mold thereof.

### Description of Related Art

Power module is a module that can integrate one or more power components and the dies of power semiconductor components and package them together, and has been widely used in the areas such as cars and motorcycles, industrial equipment, household electric appliances, etc. In general, the power module is provided for installing one or more power components or power semiconductor components on a circuit substrate, and then packaging the power components by a material such as an epoxy molding compound (EMC) to protect the dies and internal components of the power components.

In addition, it is often necessary to provide different types of power modules and sufficient housing materials in correspondence with the power modules in production, and add an additional process for the assembling, incurring a higher material cost and a more time-consuming assembly process.

However, the related-art power modules are often reassembled in a casing for protection after the packaging is completed. As a result, the terminal signals of the EMC packaging structure in correspondence with mold tolerance are only horizontal, and the signal may be lost easily when switching the silicon carbide (SiC) or gallium nitride (GaN) modules at high speed. In addition, it is often necessary to provide enough housing materials to match different types of power modules, and it is also necessary for the production to add an assembly process, resulting in higher material costs and more time-consuming assembly process.

In view of the aforementioned drawbacks of the prior art, this discloser conducted extensive research and developed a power module with a reasonable design to overcome the drawbacks of the related art.

### SUMMARY OF THE DISCLOSURE

It is a primary objective of this disclosure to provide a power module, and a manufacturing method and a mold thereof, which may reduce signal disparity by making the vertically set terminals closer to the dies and other components through the packaging process, and eliminate or replace the related-art casing to achieve the purpose or effect of reducing the assembly process and lowering the material cost in production.

To achieve the aforementioned and other objectives, this disclosure discloses a power module including a circuit substrate, at least one terminal assembly, and a package body. A first surface of the circuit substrate is provided with at least one semiconductor component, each terminal assembly includes a terminal rack, and a terminal inserted into the terminal rack, each terminal rack is disposed on the first surface of the circuit substrate, each terminal rack has an insert surface provided for each terminal to pass through and insert into the terminal rack for a combination, a package body is installed on the circuit substrate for packaging the semiconductor component, and the package body has an external surface substantially aligned with the insert surface of each terminal rack or provided for protruding the insert surface, such that each terminal is protruded out of the package body.

To achieve the aforementioned objective, this disclosure provides a manufacturing method for a power module, and the method includes the steps of:
a) preparing a circuit substrate, wherein the circuit substrate comprises at least one semiconductor component installed thereon;
b) installing at least one terminal rack on the circuit substrate, and conducting the semiconductor component with the terminal rack by a bonding wire for an electrical conduction, wherein the terminal rack comprises a jack for inserting a terminal;
c) sealing the jack of the terminal rack, and performing an in-mold injection process to form a package body on the circuit substrate for packaging the semiconductor component and the terminal rack; and
d) inserting the terminal into the jack on the terminal rack.

To achieve the aforementioned objective, this disclosure provides a mold for manufacturing a power module, the mold is used for performing a packaging process of a circuit substrate, and the circuit substrate includes at least one terminal rack with a jack. The mold includes a lower mold, an upper mold, and an elastic pressing plate, the lower mold includes a lower mold cavity, the upper mold includes an upper mold cavity corresponding to the lower mold cavity, the lower mold cavity and upper mold cavity jointly form a space for placing the circuit substrate and the terminal rack, the elastic pressing plate is installed above the upper mold and includes a pressing member and an elastic member, the pressing member passes through the upper mold toward the jack of the terminal rack, the elastic member provides an elastic force to the pressing member to make pressing member abut against and seal the jack.

### BRIEF DESCRIPTION OF THE DRAWINGS

FIG. 1 is a top view of a power module of a first embodiment of this disclosure;

FIG. 2 is a bottom view of a power module of the first embodiment of this disclosure;

FIG. 3 is a top view showing the internal structure of a power module of the first embodiment of this disclosure, wherein a package body is represented by an imaginary line such that the internal structure can be seen;

FIG. 4 is a side view showing the internal structure of a power module of the first embodiment of this disclosure, wherein a package body is represented by an imaginary line such that the internal structure can be seen;

FIG. 5 is a schematic view of a second embodiment of this disclosure, which is shown by the representation method as depicted in FIG. 3;

FIG. 6 is a schematic view of the second embodiment of this disclosure, which is shown by the representation method as depicted in FIG. 4;

FIG. 7 is a schematic view of a third embodiment of this disclosure, which is shown by the representation method as depicted in FIG. 3; and

FIG. 8 is a schematic view of a mold of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

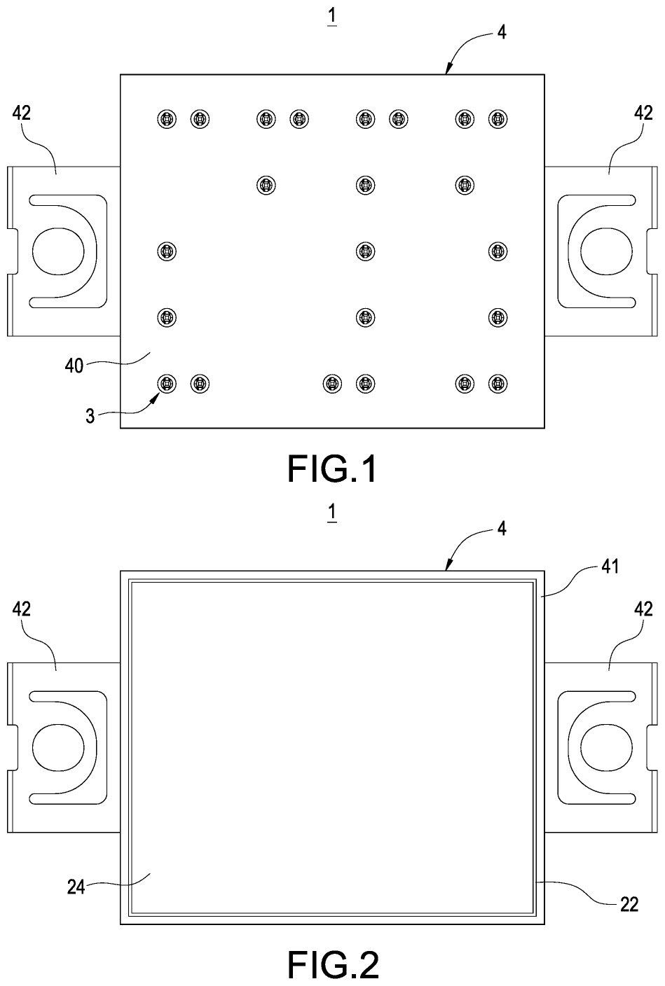

With reference to FIGS. 1 to 4 for the top and bottom views of a power module and the schematic top and side views of the power module in accordance with this disclosure respectively, this disclosure provides a power module, and a manufacturing method and a mold thereof, and the power module 1 includes a circuit substrate 2, at least one terminal assembly 3, and a package body 4.

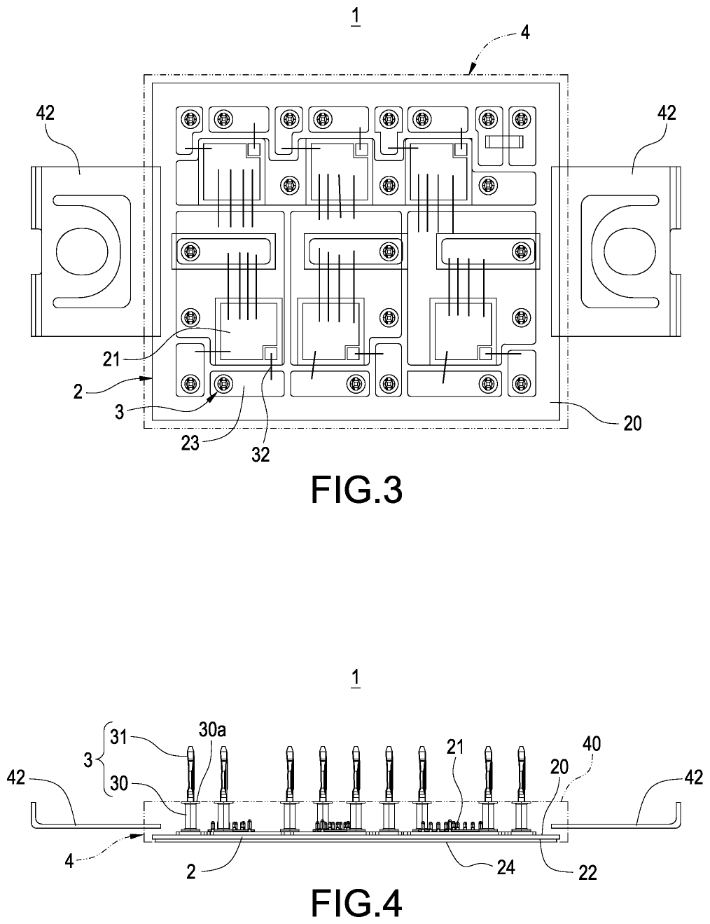

In FIGS. 3 and 4, the circuit substrate 2 is a ceramic substrate made of a ceramic material, which is sealed on the bottom surface of the package body 4. The circuit substrate 2 has a first surface 20, one or more semiconductor components 21 installed on the first surface 20, and the semiconductor component 21 is a power component such as an Insulated Gate Bipolar Transistor (IGBT). The circuit substrate 2 further has a second surface 22 opposite to the first surface 20. In an embodiment of this disclosure, the circuit substrate 2 uses the first surface 20 as a main plane provided for soldering the terminal assembly 3, so that the circuit substrate 2 has at least one conductive layer 23 on the first surface 20, and the conductive layer 23 is generally adjacent to any one side of any one semiconductor component 21. In addition to the purpose of soldering the terminal assembly 3, the conductive layer 23 may also be used for an electrical conduction with the semiconductor component 21, and the first surface 20 may be packaged inside the package body 4, while the second surface 22 is adjacent to or exposed from the bottom surface of the package body 4 (as shown in FIG. 2 or FIG. 4).

In FIGS. 3 and 4, each terminal assembly is mainly made of a conductive material and includes a terminal rack 30, and a terminal 31 inserted into the terminal rack 30, and each terminal rack 30 is installed on the first surface 20 of the circuit substrate 2. In a specific embodiment, the terminal rack 30 is electrically connected to the conductive layer 23 of the circuit substrate 2, and connected to the conductive layer 23 and the semiconductor component 21 by a bonding wire 32 for an electrical conduction. In addition, each terminal rack 30 has an insert surface 30a, and a jack 30b concavely formed on the insert surface 30a (Refer to FIG. 8), and provided for passing each terminal 31 through the insert surface 30a to insert into the jack 30b of the terminal rack 30, so as to combine the terminal 31 with the terminal rack 30. In a specific embodiment of this disclosure, the terminal assembly 3 is formed by a nut and a screw (or bolt), and the nut and the screw (or bolt) are also made of a conductive material. The terminal rack 30 may be the nut, and the terminal 31 may be the screw (or bolt). By installing the terminal rack 30 formed by the nut onto the circuit substrate 20 and passing the terminal 31 formed by the screw or bolt into a screw hole of the nut (which is the jack 30b) to screw and combine the terminal rack 30 and the terminal 31.

In FIGS. 1 to 4, the package body 4 is installed on the circuit substrate 2 for packaging the semiconductor component 21 on the circuit substrate 2 by an in-mold injection process, and the package body 4 is formed by a packaging material such as an epoxy molding compound (EMC). The formed package body 4 has an external surface 40 substantially aligned with the insert surface 30a of each terminal rack 30, or the insert surface 30a protruding from the external surface 40, so as to make each terminal 31 protrude out of the package body 4. In FIGS. 2 and 4, the package body 4 further has a second external surface 41 opposite to the external surface 40, and adjacent to the second surface 22 of the circuit substrate 2, and the second surface 22 of the circuit substrate 2 is provided with a heat dissipation layer 24 which is exposed from the second external surface 41 of the package body 4, thus facilitating the power module 1 to dissipate heat during operation.

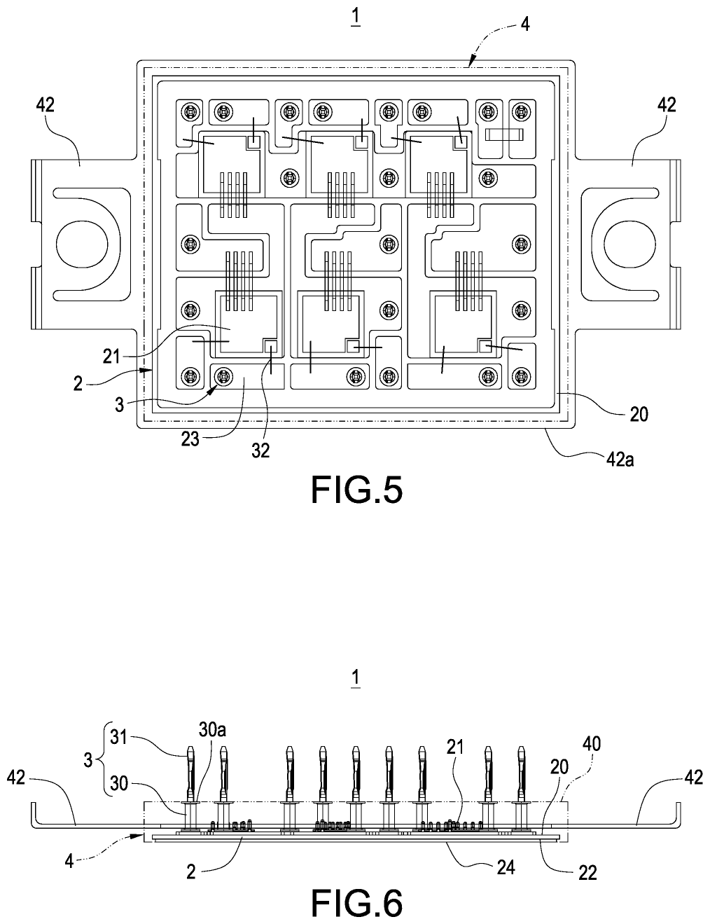

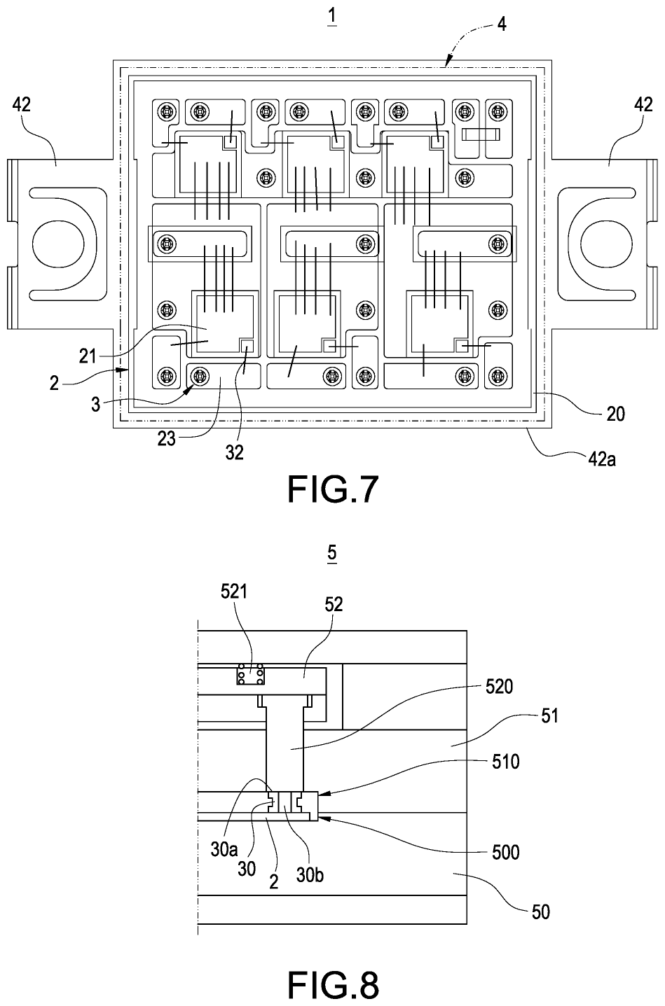

In FIGS. 3 and 4, two locking plates 42 are respectively disposed on any two opposite sides of the package body 4 for fixation, and the two locking plates 42 may be partially buried into the package body 4 during the packaging process by the package body 4, and most of the rest of the locking plates 42 are extended out of the package body 4, such that each locking plate 42 may be used for fixing the power module 1. In the second embodiment of this disclosure as shown in FIGS. 5 and 6, each locking plate 42 is connected to a frame 42a to be in a one-piece form, such that each locking plate 42 and the frame 42a jointly form a single component, and the frame 42a substantially surrounds the circuit substrate 21. During the packaging process by the package body 4, the whole of a part of the frame 42a is buried into the package body 4, such that any locking plate 42 integrally formed with the frame 42a may be extended out of the package body 4 to facilitate the package body 4 to package a plurality of locking plates 42a by the frame 42a. This embodiment has been disclosed in FIG. 7.

In addition, this disclosure further provides a manufacturing method for a power module, and the method includes the steps of: preparing a circuit substrate 2, wherein the circuit substrate 2 has at least one semiconductor component 21 installed on the circuit substrate 2; installing at least one terminal rack 30 on the circuit substrate and conducting the semiconductor component 21 with the terminal rack 30 by a bonding wire 32 for an electrical conduction; sealing the jack 30b of the terminal rack 30 and performing an in-mold injection process to form a package body 4 for packaging the semiconductor component 21 and the terminal rack 30 on the circuit substrate 2; and inserting the terminal 31 into the jack 30b on the terminal rack 30 to complete manufacturing the power module 1.

In the in-mold injection process as shown in FIG. 8, the package body 4 is formed by a mold 5, and the mold 5 is used for manufacturing the power module 1, which is for performing the packaging process of the circuit substrate 2. The mold 5 includes a lower mold 50, an upper mold 51, and an elastic pressing plate 52, the lower mold 50 has a lower mold cavity 500, and the upper mold 51 has an upper mold cavity 501 corresponding to the lower mold cavity 500, and the lower mold cavity 500 and the upper mold cavity 501 jointly form a space for placing the circuit substrate 2 and the terminal rack 30 and serving as a mold cavity for molding. The elastic pressing plate 52 is installed above the upper mold 52 and includes a pressing member 520 and an elastic member 521, the pressing member 520 passes through the upper mold 52 toward the jack 30b of the terminal rack 30, the elastic member 521 provides an elastic force to the pressing member 520 to make the pressing member 520 abut against the jack 30b, so as to seal the jack 30b. Therefore, after the packaging process by the package body 4, the jack 30b is maintained for inserting the terminal 31 to complete assembling the power module 1.

By means of the above structural assembly, the power module, manufacturing method, and mold of this disclosure are achieved.

With the structure of the power module 1, manufacturing method, and mold of this disclosure, the package body 4 is formed on the first surface 20 of the circuit substrate 2 by in-mold injection before the terminal 30 is inserted into the terminal rack 30, and then the semiconductor component 21 is packaged, so that the vertically set terminal 30 may be closer to a die such as the semiconductor component 21 to reduce signal disparity; while the external surface 40 of the package body 4 is provided for exposing the insert surface 30a of the terminal rack 30 (that is, the insert surface 30a will be exposed from the external surface 40), such that the terminal 31 may be inserted into the terminal rack 30 after the package body 4 is formed to complete the assembling. Compared with the prior art, the power module 1 of this disclosure may use the package body 4 directly to substitute the protection function by the casing after its formation and packaging without the need of installing any additional casing or cover on the circuit substrate 2, so as to simplify the manufacturing process and lower the material cost in production.

While this disclosure has been described by means of specific embodiments, numerous modifications and variations could be made thereto by those skilled in the art without departing from the scope and spirit of this disclosure set forth in the claims.

What is claimed is:

1. A power module, comprising:
a circuit substrate, comprising at least one semiconductor component installed on a first surface thereof;
at least one terminal assembly, comprising a terminal rack and a terminal inserted in the terminal rack, the terminal rack disposed on the first surface of the circuit substrate and comprising an insert surface, and the terminal combined to the terminal rack (30) by the terminal being inserted into the terminal rack through the insert surface; and
a package body, installed on the circuit substrate to package the semiconductor component, and comprising a first external surface substantially aligned with the insert surface of the terminal rack, or the insert surface protruding out from the first external surface, to make the terminal protrude out from the package body.

2. The power module according to claim 1, wherein the circuit substrate is a ceramic substrate.

3. The power module according to claim 1, wherein the circuit substrate comprises at least one conductive layer disposed thereon, the terminal rack of the terminal assembly is disposed on the conductive layer, and the conductive layer is coupled to the semiconductor component by wire bonding for electrical conduction.

4. The power module according to claim 1, wherein the circuit substrate further comprises a second surface opposite to the first surface, and a heat dissipation layer is disposed on the second surface.

5. The power module according to claim 4, wherein the heat dissipation layer is exposed from a second external surface of the package body, and the second external surface and the first external surface are opposite to each other.

6. The power module according to claim 1, wherein the semiconductor component is a power component.

7. The power module according to claim 6, wherein the power component is an insulated gate bipolar transistor.

8. The power module according to claim 1, wherein the terminal assembly comprises a nut and a screw.

9. The power module according to claim 8, wherein the terminal rack is a nut, the terminal is a screw, the nut is installed on the circuit substrate, and the screw passes through a screw hole of the nut to screw and combine with each other.

10. The power module according to claim 1, wherein the package body is made of an epoxy molding compound (EMC) as a packaging material.

11. The power module according to claim 1, wherein two locking plates are separately disposed any two sides of the package body opposite to each other for fixation, and each locking plate is extended out from the package body.

12. The power module according to claim 11, wherein each locking plate is connected by a frame to be in a one-piece form, and the frame is at least partially buried in the package body.

13. A manufacturing method for a power module, the manufacturing method comprising the steps of:
a) preparing a circuit substrate, wherein the circuit substrate comprises at least one semiconductor component installed thereon;
b) installing at least one terminal rack on the circuit substrate, and conducting the semiconductor component with the terminal rack by a bonding wire for an electrical conduction, wherein the terminal rack comprises a jack for inserting a terminal therein;
c) sealing the jack of the terminal rack, and performing an in-mold injection process to form a package body on the circuit substrate of packaging the semiconductor component and the terminal rack; and
d) inserting a terminal into the jack on the terminal rack.

14. A mold for manufacturing a power module, used for performing a packaging process of a circuit substrate, the circuit substrate comprising at least one terminal rack, the terminal rack comprising a jack, and the mold comprising:
a lower mold, comprising a lower mold cavity;
an upper mold, comprising an upper mold cavity corresponding to the lower mold cavity, the lower mold cavity and the upper mold cavity jointly defining a space for placing the circuit substrate and the terminal rack therein; and
an elastic pressing plate, installed above the upper mold, and comprising a pressing member and an elastic member, the pressing member passing through the upper mold toward a jack of the terminal rack, and the elastic member providing an elastic force to make the pressing member abut against and seal the jack.
